(19) United States
(12) Patent Application Publication
(10) Pub. No.: US 2015/0002168 A1
(43) Pub. Date: Jan. 1, 2015

(54) SYSTEMS AND METHODS FOR SOFT-FIELD TOMOGRAPHY

(71) Applicant: General Electric Company, Schenectady, NY (US)

(72) Inventors: Tzu-Jen Kao, Watervliet, NY (US); David Michael Davenport, Schenectady, NY (US); Jeffrey Michael Ashe, Gloversville, NY (US); Xiaohui Chen, Schenectady, NY (US)

(21) Appl. No.: 13/929,362

(22) Filed: Jun. 27, 2013

(51) Int. Cl. G01R 27/02

(52) U.S. Cl. CPC G01R 27/02
USPC 324/600

(57) ABSTRACT

One system includes a pattern generator that generates one or more excitation patterns suitable for probing a hydration level of a tissue of a subject at one or more depths from a surface of the subject into an interrogation region. Each of the excitation patterns has a spatial sensitivity at one of the one or more predetermined depths. A data analysis module receives one or more measured responses of the subject at a plurality of electrodes to excitation applied by the plurality of electrodes based on the one or more excitation patterns and determines one or more hydration changes at the one or more depths within the subject based on the measured responses. Each of the measured responses corresponds to the one of the one or more predetermined depths for which the applied excitation pattern has spatial sensitivity.

### BACKGROUND

The subject matter disclosed herein generally relates to soft-field tomography systems and methods and, more particularly, to systems and methods of generating soft-field tomography excitations for probing an object or subject at multiple depths.

Soft-field tomography, such as electrical impedance spectroscopy (EIS), electrical impedance tomography (EIT), diffuse optical tomography, elastography, thermography, and so forth, is used to non-invasively probe the internal properties of an object or subject, such as the electrical properties of materials or internal structures within the object or subject. For example, in EIS/EIT systems, an estimate of the distribution of electrical conductivities of probed internal structures is made and utilized to reconstruct the conductivity and/or permittivity of the materials within the probed area or volume. The reconstruction is based on using the estimate along with an applied excitation pattern to electrodes placed on the surface of the interrogation region of the object or subject and a measured response of the interrogated volume to the applied excitations detected at the surface of the interrogation region. In some cases, visual representations of the estimates are then formed and may be utilized, for example, by a medical practitioner to identify clinically relevant information about the object or subject.

In conventional physiological electrical impedance instruments, a single excitation pattern, such as from a single electrical voltage or current source, is used to obtain the desired measurements. This single excitation pattern gives rise to a measurement representative of an approximation of the bulk impedance of the entire interrogated region of the object or subject. That is, use of a single excitation pattern gives rise to a lack of control over the current path or potential field generated in the region of interest in the subject, and a corresponding control system is therefore unable to determine the location of the signal arising from probing the subject. Additionally, in many medical applications, the bulk impedance measurement of the interrogation region may be affected by clinically irrelevant factors, such as a subject's skin condition, body position, size, gender, age, race and so forth, thus impacting the ability of a medical practitioner to identify the desired clinically relevant measurement. Accordingly, there exists a need for soft-field tomography systems and methods that address these drawbacks.

### BRIEF DESCRIPTION

In one embodiment, a soft-field tomography system includes a plurality of electrodes for positioning on a surface of an interrogation region of a subject. The system also includes a pattern generator that determines one or more excitation patterns for probing a tissue of the subject at one or more predetermined depths from the surface of the subject into the interrogation region. Each of the one or more excitation patterns has a spatial sensitivity at one of the one or more predetermined depths. A plurality of excitation sources is coupled to the plurality of electrodes and for applying each of the one or more excitation patterns to the plurality of electrodes to excite the plurality of electrodes substantially simultaneously with each of the excitation patterns. A plurality of receivers is coupled to the plurality of electrodes for measuring one or more responses of the subject at the plurality of electrodes to the excitation applied by the plurality of electrodes. Each of the one or more responses corresponds to one of the one or more predetermined depths for which the applied excitation pattern has spatial sensitivity.

In another embodiment, a soft-field tomography system includes a pattern generator that generates one or more excitation patterns suitable for probing a hydration level of a tissue of a subject at one or more predetermined depths from a surface of the subject into an interrogation region of the subject. Each of the one or more excitation patterns has a spatial sensitivity at one of the one or more predetermined depths. A data analysis module receives one or more measured responses of the subject at a plurality of electrodes to excitation applied by the plurality of electrodes based on the one or more excitation patterns, and determines one or more hydration changes at the one or more predetermined depths within the subject based on the one or more measured responses. Each of the one or more measured responses corresponds to the one of the one or more predetermined depths for which the applied excitation pattern has spatial sensitivity.

In another embodiment, an electrical impedance based imaging method, includes applying first excitation signals to a plurality of electrodes positioned on a surface of an interrogation region of a subject, measuring a first response of the interrogation region of the subject to the excitation applied by the plurality of electrodes based on the first excitation signals, applying second excitation signals to the plurality of electrodes, and measuring a second response of the interrogation region of the subject to the excitation applied by the plurality of electrodes based on the second excitation signals. The method also includes determining at least one conductivity level at one or more depths below the surface of the subject based on the first response and the second response

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a schematic illustrating an embodiment of an electrical impedance spectroscopy or tomography system;

FIG. 2 is a block diagram illustrating example components of an electrical impedance spectroscopy or tomography system in accordance with an embodiment;

FIGS. 3A-3G are schematics illustrating example current patterns that may be generated by exciting a plurality of electrodes in accordance with presently disclosed embodiments;

FIG. 4 illustrates an embodiment of a method for generating one or more desired current patterns in a subject and performing a reconstruction based on a measured response;

FIG. 5A illustrates an example of a reconstruction result that may be generated when two or more current patterns are utilized to probe multiple tissue depths in accordance with an embodiment;

FIG. 5B illustrates an example of a reconstruction result constructed in a two dimensional array format and displaying only a region of interest in accordance with an embodiment;

FIG. 5C illustrates an example of a reconstruction result generated in a laboratory experiment in which an imaged chicken breast had a dry surface;

FIG. 5D illustrates an example of a reconstruction result generated in a laboratory experiment in which an imaged chicken breast had a wet surface;

FIG. 6 illustrates example reconstructed plots representing experimental results obtained when a chicken breast was injected with different volumes of saline;

FIG. 7 illustrates an example of a reconstruction data flow in accordance with an embodiment;

FIG. 8 illustrates an embodiment of a method in which reconstruction data is normalized to the impedance of a reference depth; and

FIG. 9 illustrates a plurality of frequency sweep plots generated when a subject having one leg elevated for 30 min and the other control leg in supine position. It was imaged in a laboratory in accordance with an embodiment.(It is better to add another arrow and box pointing to the group of frequency sweep plots corresponding to the elevated leg)

### DETAILED DESCRIPTION

As described in more detail below, provided herein are embodiments of soft-field tomography methods and systems that provide for generation of multiple excitations to probe a subject at one or multiple, distinguishable depths or layers (i.e., depth ranges) below the surface of the subject to identify depth or layer specific impedance or hydration information. The foregoing feature may offer advantages over traditional electrical impedance systems that acquire bulk impedance measurements since the presently disclosed systems and methods are capable of acquiring measurements that are insensitive to conditions present at the surface of a subject's skin. While these systems are compatible with any application in which depth or layer specific impedance information is desired, presently disclosed embodiments may offer advantages, for example, but not limited to edema monitoring medical applications in which it may be desirable to detect, monitor, track, and/or trend peripheral edema (e.g., in subjects with congestive heart failure, chronic kidney disease, hypertension, etc.). In such applications, presently disclosed systems or methods may be implemented to measure or monitor the hydration level of the subject's affected tissue.

In certain imaging applications, a hydration or edema level is highly correlated with obtained impedance measurements because different water contents give rise to different impedance readings. Again, one advantage over existing methods and systems is gained by using multiple-source excitation patterns to detect impedance changes at different depths within a subject. As compared to traditional systems, presently disclosed methods may be more sensitive to hydration level at different depths within tissues and less sensitive to different skin conditions.

It should be noted that presently disclosed embodiments may be used in different working frequencies (e.g., K Hz for impedance, M˜G Hz for microwave, T Hz for optical, etc.) at different electrode configurations (linear electrode array, 2D electrode array, cylinder/spherical electrode configurations, etc.). Further, the impedance-derived hydration level may be reconstructed in two or three dimensional format, or reduced to a one dimensional hydration index at a certain depth, depending on implementation-specific considerations.

Additionally, it should be noted that as used herein, the term “soft-field tomography” refers to any tomography or spectroscopy system in which the electromagnetic field generated to probe an object or subject propagates across the entire probed volume. As such, in soft-field tomography systems, the measurement acquired at the surface of the interrogated volume depends on the values of the measured quantity in the entire volume, for example, as opposed to along a probed path as in hard-field tomography systems. Examples of soft-field tomography systems in which the presently disclosed embodiments may be utilized include but are not limited to electrical impedance spectroscopy (EIS), electrical impedance tomography (EIT), diffuse optical tomography (DOT), near infrared spectroscopy (NIRS), elastography, thermography, microwave tomography, or any other related modality or combination of modalities.

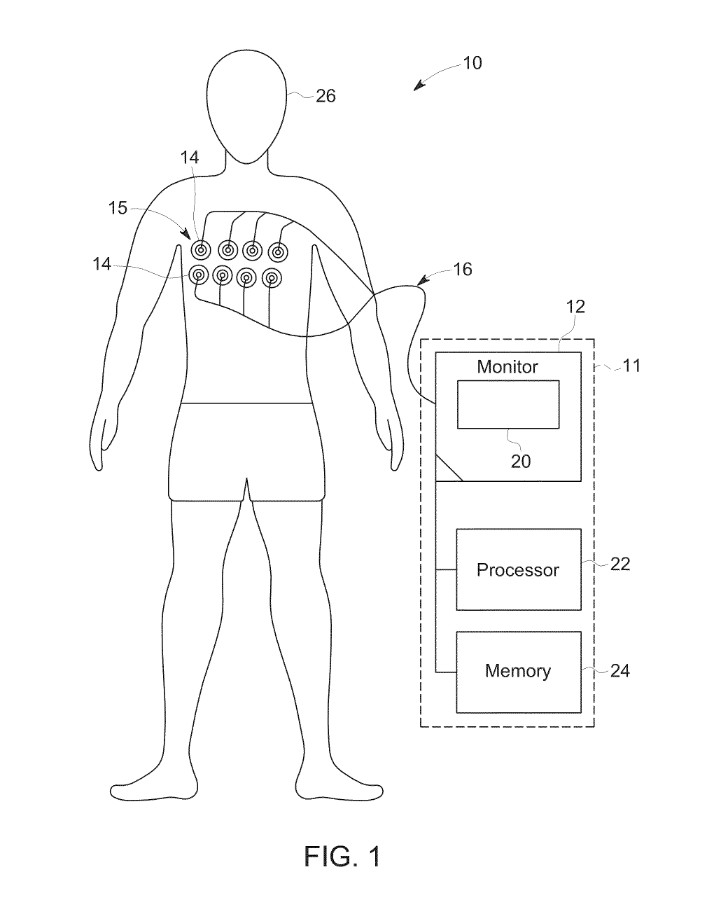

With the foregoing discussion in mind, one embodiment of a soft-field tomography system 10 is illustrated in FIG. 1. For example, the soft-field tomography system 10 may be an EIT or EIS system that is configured to estimate the electrical properties (e.g., conductivity and/or permittivity) inside a body or object using measurements obtained on the surface of the body or object (i.e., non-invasively). Depending on the system, spectroscopic data based on the measured electrical properties and/or tomographic representations spatially depicting the electrical properties (or values derived from such electrical properties) within the body may be generated and/or displayed. For example, in accordance with some presently disclosed embodiments, one or more hydration changes between one or more depths or layers of tissues within the body may be estimated using the electrical properties measured by the system 10.

In the depicted example, the system 10 includes a monitoring and processing system 11 including a monitor 12, a display 20, a processor 22, and a memory 24, as well as an array of sensors (i.e., electrodes 14) and communication cables 16. In the illustrated embodiment, the electrodes 14 are provided as an array on a surface 15 of a chest of a subject 26 above an interrogation region of the subject 26 (i.e., the subject's anatomy below the outer surface of the chest). However, it should be noted that in other embodiments, the electrodes 14 may be positioned on or about any desired portion of the subject's anatomy, such as but not limited to the chest, an arm, a leg, and so forth, or on any desired portion of another object or subject proximate to a desired interrogation region. For further example, in other embodiments, the electrodes 14 may be positioned on the surface of the subject or object, near the surface of the subject or object, or penetrating the surface of the subject or object, depending on implementation-specific considerations. Accordingly, it should be noted that the electrodes 14 may take on a variety of different forms, such as surface-contacting electrodes, stand-off electrodes, capacitively coupled electrodes, conducting coils, antennas, and so forth. Additionally, the electrodes may be arranged in any desired spatial distribution, such as linear arrays, rectangular arrays, etc.

Further, different quantities (e.g., 8, 16, 32, and so forth) and arrangements (e.g., adhesive individual electrodes, electrodes provided on a pad, etc.) of electrodes 14 may be provided in different embodiments. In certain embodiments, coupling between the subject 26 and the electrodes 14 may be achieved by an adhesive portion (e.g., a tacky base layer) of the electrodes 14 or a component to which the electrodes 14 are attached. For example, in some embodiments, the electrodes 14 may be provided attached to or otherwise integrated with a compliant pad or substrate that may be positioned or placed on the subject 26.

During operation, the electrodes 14 communicate with the monitor 12, which may include one or more driving and/or controlling circuits for controlling operation of the electrodes 14, such as to inject current at desired patterns or to generate a readout signal at each electrode. In one such embodiment, each electrode 14 is independently addressable by the drive or control circuitry. The drive and/or control functionality may be provided as one or more application specific integrated circuits (ASICs) within the monitor 12 or may be implemented using one or more general or special-purpose processors 22 used to execute code or routines for performing such control functionality.

In addition, one or more of the processors 22 may provide data processing functionality with respect to the signals read out using the electrodes 14. For example, a processor 22 may execute one or more stored processor-executable routines that may process signals derived from the measured electrical signals to generate depth or layer specific tissue hydration data, such as numeric values or tomographic representations, as discussed herein. Further, the routines executed by the processor 22 and/or the data processed by the processor 22 may be stored on a storage component (i.e., memory 22 or other suitable storage structures in communication with the processor 22). Suitable storage structures include, but are not limited to, one or more memory chips, magnetic or solid state drives, optical disks, and so forth, suitable for short or long-term storage. The storage component may be local or remote from the processor 22 and/or system 10. For example, the storage component may be a memory 24 or storage device located on a computer network that is in communication with the processing component 22. In the present context, the storage component may also store programs and routines executed by the processing component 22, including routines for implementing the presently disclosed approaches for measuring or monitoring tissue hydration at multiple desired depths or layers.

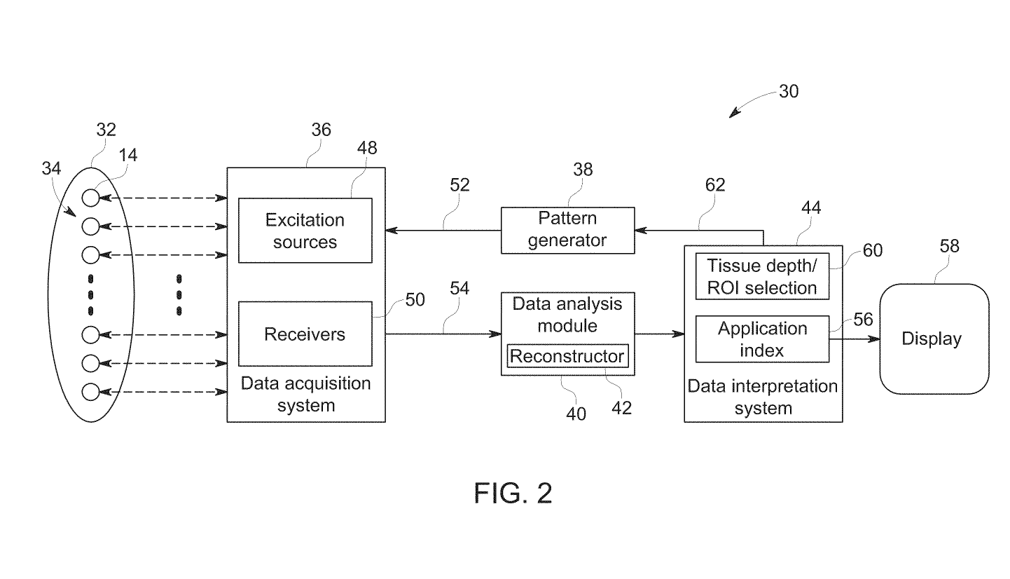

With the foregoing in mind, FIG. 2 depicts a block diagram of a soft-field tomography system 30 in accordance with a presently disclosed embodiment. The illustrated system 30 includes the electrode 14 positioned on a subject 32 having a surface 34 above an interrogation region. The system 30 also includes a data acquisition system 36 coupled to a pattern generator 38 and a data analysis module 40 having a reconstructor 42. Additionally, in the illustrated embodiment, an optional data interpretation system 44 and display 58 are provided.

During operation, a plurality of excitation sources 48 and a plurality of receivers 50 are coupled to the electrodes 14 for the purpose of exciting the plurality of electrodes 14 to generate a signal that propagates through the interrogation region of the subject 32 and measure the response of the subject 32 to the excitations. The excitation sources 48 may be voltage sources or current sources and operate at a desired working frequency (e.g., approximately 100 Hz to approximately 10 M Hz). In some embodiments, each of the plurality of excitation sources 48 may be dedicated to one of the plurality of electrodes 14 and configured to generate an excitation signal for the dedicated one electrode. Further, the pattern generator 38 is coupled to the excitation sources 48 to communicate desired excitation patterns to the excitation sources 48. The excitation sources 48 may be single source or multiple source, and a single source or multiple source excitation pattern may be utilized. If a single source excitation pattern is desired, the excitation pattern is constructed by using a single excitation source on the electrodes 14. However, in embodiments in which a multiple source excitation pattern is desired, the excitation pattern is constructed by using multiple excitation sources on the electrodes 14. For example, multiple currents may be applied to the electrodes 14 at the same time.

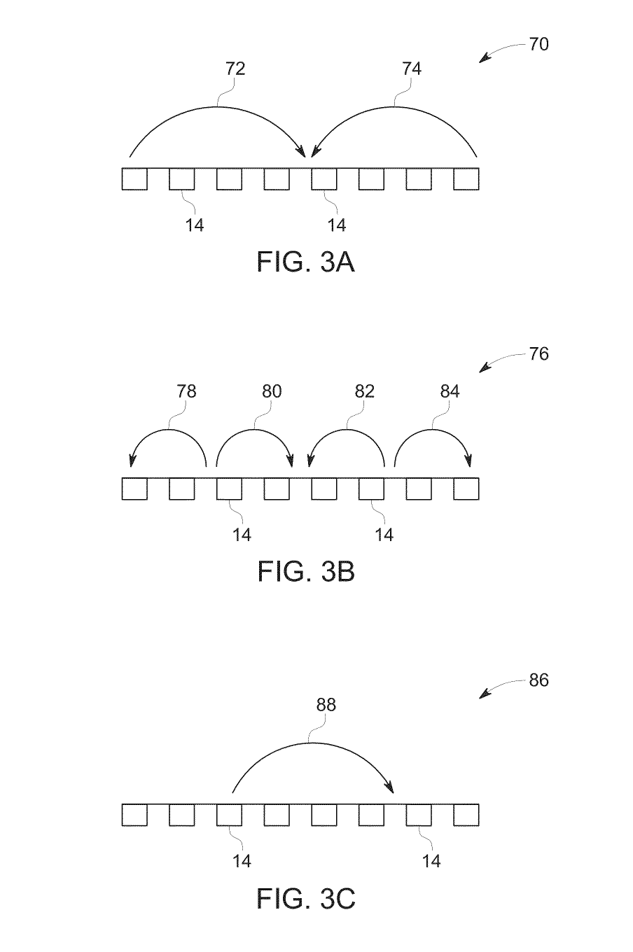

In some embodiments in which distinguishable depth or layer specific information is desired, the pattern generator 38 is configured to determine two or more patterns suitable for probing a tissue of the subject 32 at one, two, or more depths or layers from the surface of the subject 32 into the interrogation region. These patterns may be chosen, for example, based on the type of medical information desired by the clinician, features of the subject, subject history, feedback received based on prior patterns used with a given subject, or any other relevant factor or combination of factors provided to the pattern generator 38. Examples of suitable current patterns are illustrated and described in more detail below with respect to FIGS. 3A-G.

Further, during operation, the pattern generator 38 generates two or more excitation patterns, as illustrated by arrow 52 that correspond to the two or more current patterns determined to be appropriate for the given medical application. These excitation patterns are communicated to the excitation sources 48 such that the electrodes 14 may be appropriately excited during data acquisition. In some embodiments, each of the generated excitation patterns may include the current magnitude and polarity (e.g., direction) for each of the electrodes 14 suitable for forming the desired pattern within the interrogation region of the subject 32. That is, presently disclosed embodiments provide for each of the electrodes 14 to be independently controlled at different current magnitudes and polarities, thus giving rise to generation of more than one pattern within the object 32 and enabling the ability to acquire depth or layer specific information by using two or more current patterns.

It should be noted, however, that in certain embodiments, each current pattern may be generated at a different time than each other current pattern, but during generation of a given current pattern, all of the electrodes 14 may be simultaneously activated. That is, during one example excitation operation, a first excitation pattern may be applied to each of the electrodes 14 concurrently, and the corresponding response to the first excitation pattern may be measured by receivers 50. Subsequently, a second excitation pattern may be applied to the electrodes 14 concurrently, and the corresponding response to the second excitation pattern may be measured by receivers 50. The operation may proceed in this manner until all the desired excitation patterns are utilized.

Once the measured responses are obtained in this manner, the measured responses are communicated to the data analysis module 40, as indicated by arrow 54. The data analysis module 40 receives the measured responses of the subject 32 to the excitation applied by the electrodes 14 based on the excitation patterns 52. Depending on the given implementation, the data analysis module 40 and/or the reconstructor 42 may reconstruct a conductivity distribution at multiple depths or layers within the subject 32, calculate one or more impedance changes at multiple depths or layers within the subject 32, determine one or more hydration level changes at multiple depths or layers within the subject 32, and/or quantify an edema level at each of the depths or layers within the subject 32.

Further, it should be noted that although in many of the embodiments discussed herein, impedance values and changes are determined for multiple depths or layers, in other embodiments, an impedance, hydration, or edema level may be determined for a single depth or layer within a subject. That is, embodiments of the presently disclosed systems and methods may enable depth or layer specific information to be obtained even if information is only desired at a single depth or layer. The foregoing feature may offer advantages over existing systems that only enable bulk impedance measurements to be obtained and do not enable determination of depth or layer specific information even at a single depth or layer.

For example, in some embodiments in which the medical application is hydration monitoring, the data analysis module 40 may generate an application specific index 56 related to the subject's edema level that is communicated to the data interpretation system 44. The data interpretation system 44 may then provide this index 56 to a display 58, for example, for visualization by a medical caregiver. The medical caregiver may also communicate information regarding the depth, layer, or region of interest within the subject 32, for example, via the selection option 60. In other embodiments, however, the selection 60 may be provided automatically or based on other received input or feedback. Additionally, it should be noted that in some embodiments, the data interpretation system 44 may provide feedback, as indicated by arrow 62, to the pattern generator 38, for example, in implementations in which it is desirable to adapt the excitation patterns 52 based on the response of the subject 32 or other relevant factors.

FIGS. 3A-G illustrate examples of current patterns that may be generated in an interrogation region of an object or subject by an eight electrode system in accordance with disclosed embodiments. However, the illustrated patterns are not meant to limit presently contemplated embodiments. Indeed, many other current patterns may also be generated by the pattern generator 38 in accordance with other embodiments. Turning now to the illustrated schematics, a current pattern 70 shown in FIG. 3A includes first and second current density lines 72 and 74 each generated by driving the electrodes 14 simultaneously but at different levels and directions. For example, the density lines 72 and 74 may be achieved by driving the outer electrodes at a positive current and the inner electrodes at a negative current, thus driving the current density lines inward.

Similarly, the current pattern 76 illustrated in FIG. 3B may be generated by separately controlling the activation of each of the electrodes 14 such that current density lines 78, 80, 82, and 84 are generated. Likewise, the current pattern 86 illustrated in FIG. 3C may be generated by separately controlling the activation of each of the electrodes 14 such that the current density line 88 is generated. In a similar manner, current patterns 90, 92, 94, and 96 may be generated as shown in FIG. 3D, FIG. 3E, FIG. 3F, and FIG. 3G, respectively, by separately controlling the activation of each of the electrodes 14 such that the current density lines 98, 100, 102, 104, 106, 108, 110, 112, 114, 116, 118, 120, 122, 124, 126, 128, 130, and 132 are generated. Again, FIGS. 3A-G are merely illustrative of examples of suitable current patterns. In other embodiments, the potential on the electrodes may be driven to achieve space scaling and create any desired current density or field within the interrogation region of the object or subject.

During operation, one or more of the illustrated current patterns may be utilized to obtain clinically useful information. For example, when the excitation sources are operated to apply an excitation pattern on the electrodes, a potential field or waveform is generated in the interrogated region. Different excitation patterns may be employed to form different potential fields or waveforms that have different sensitivities at different depths. For example, FIG. 3A is a low spatial frequency excitation pattern and it is capable of probing deeper tissue than FIG. 3F, which is a higher spatial frequency excitation pattern.

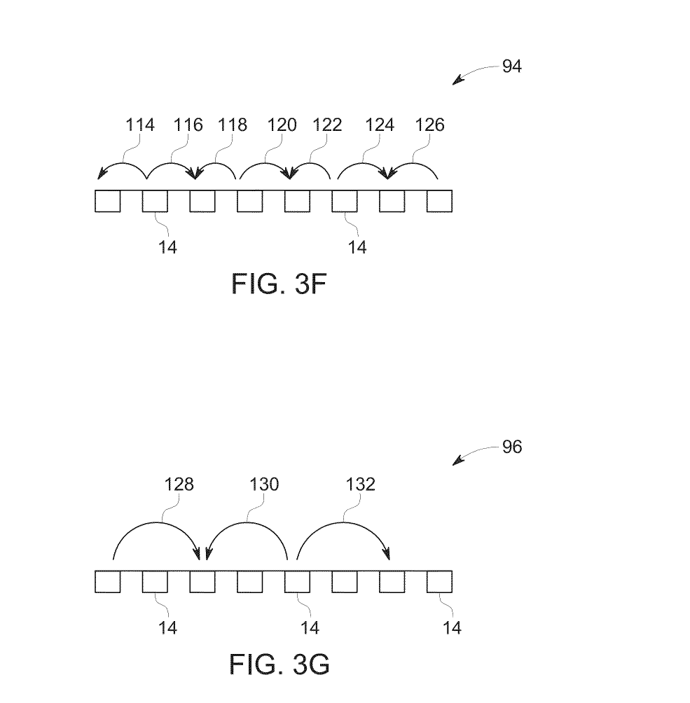

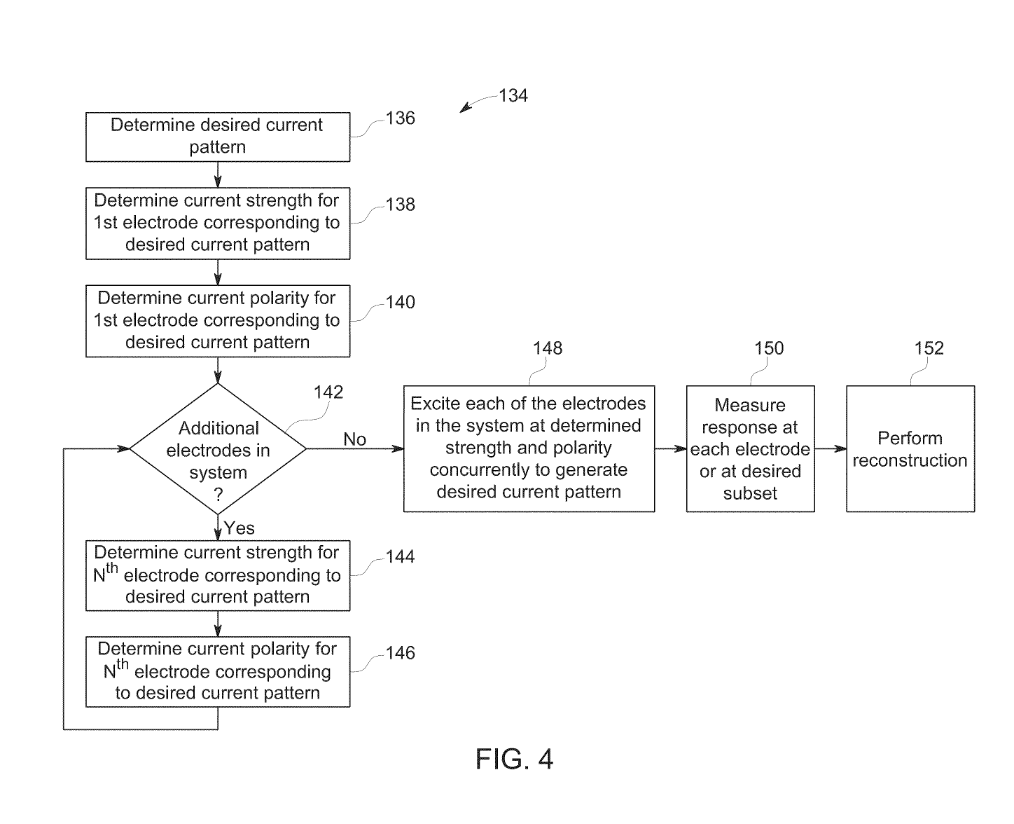

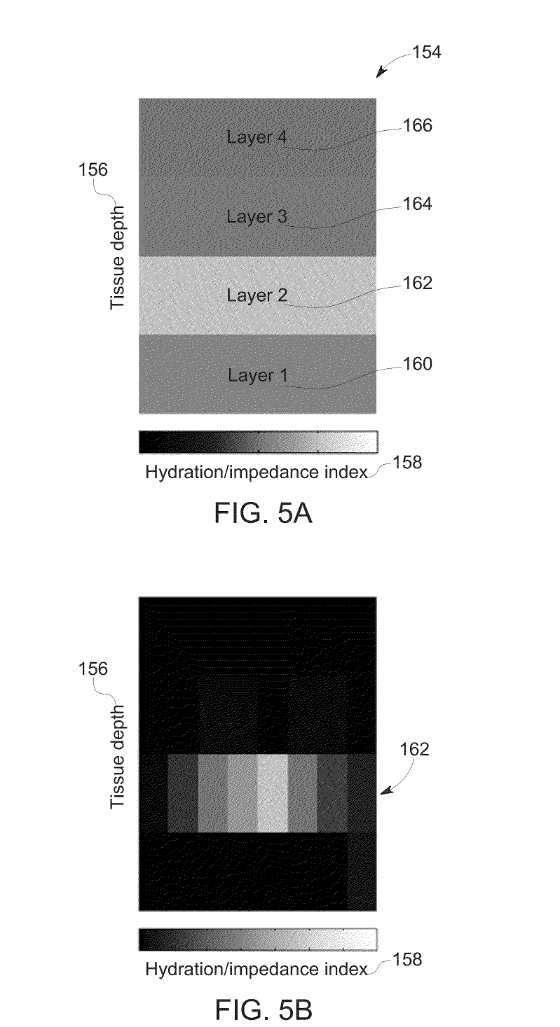

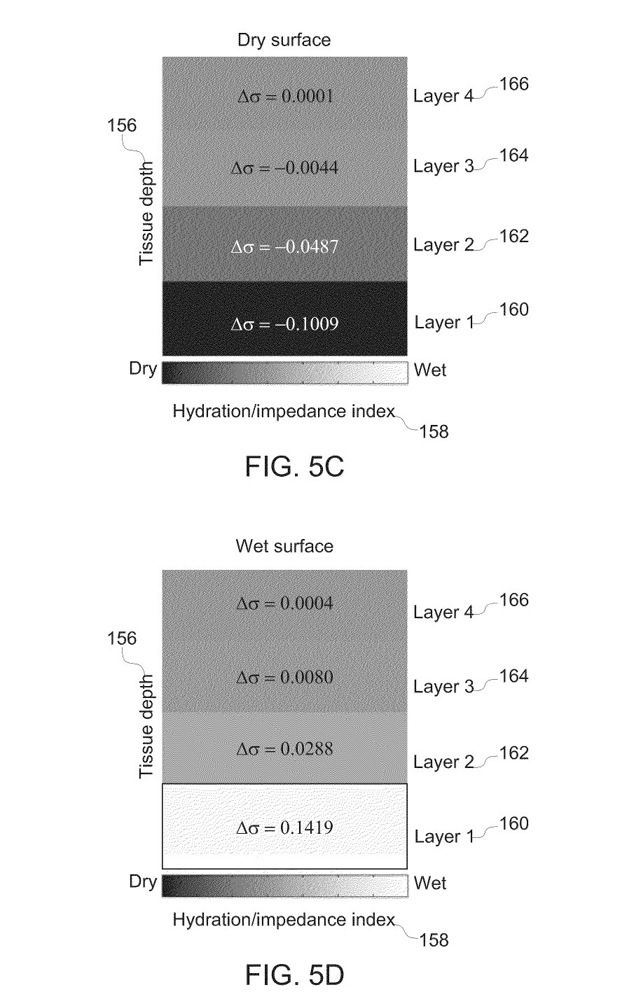

Further, during operation, by using an excitation pattern, one can obtain a corresponding pattern response. To reconstruct an image such as the one shown in FIG. 5A, multiple excitation patterns and their corresponding responses are utilized to calculate the potential distribution and reconstruct the impedance image. In certain embodiments, the more excitation patterns are applied, the more accurate the impedance image that may be reconstructed. Multiple-source excitation patterns can generate the patterns that sweep the region of interest with different spatial sensitivity patterns (e.g., FIG. 3A-3G), which can offer the reconstructor with optimal spatial information.

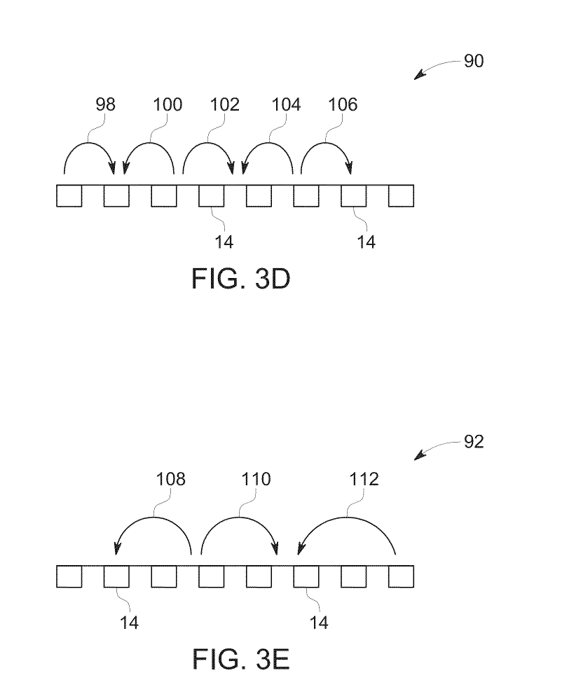

FIG. 4 illustrates an embodiment of a method 134 that may be implemented, for example, by a processor located in pattern generator 38 to generate the desired current patterns suitable for obtaining information at multiple depths or layers within the interrogation region. As illustrated, the method 134 includes determining a desired current pattern (block 136) and determining a current strength and polarity (e.g., direction) for the first electrode of the plurality of electrodes used to probe the subject that is consistent with generation of the desired current pattern (blocks 138 and 140). The method 134 then inquires as to whether additional electrodes are present in the electrode array (block 142) and, if so, determines the current strength and polarity for each of the additional electrodes in the array suitable for generating the desired current pattern (blocks 144 and 146). This process is repeated until a current strength and polarity corresponding to the desired current pattern has been determined for each of the electrodes in the array.

Once the commanded strength and polarities for each of the electrodes has been determined, the method 134 calls for exciting the plurality of electrodes concurrently, but each at the strength and polarity determined to be suitable for that electrode (block 148). Once the interrogation region of the subject has been excited in this manner, the response at each electrode is measured (block 150) and a reconstruction is performed (block 152) if the final current pattern has been applied. That is, in some embodiments, multiple current patterns may be applied in succession, and the measured responses obtained after probing with each of the patterns may be combined to generate the reconstruction.

FIG. 5A illustrates an example of a reconstruction 154 that may be generated when two or more current patterns are utilized to probe one or more tissue depths or layers of interest in accordance with an embodiment. As shown, the example reconstruction 154 is a plot of tissue depth 156 versus hydration/impedance index 158 obtained by probing a first layer 160, a second layer 162, a third layer 164, and a fourth layer 166 with eight electrodes 14, with the first layer 160 being positioned closest to the electrodes during data acquisition. As shown, by utilizing multiple excitation patterns, the conductivity differences between the layers 160, 162, 164, and 166 may be distinguished. Again, it should be noted that in certain embodiments, the reconstruction may include a conductivity plot, a hydration level plot, an edema level plot, or any other desired plot illustrating the depth or layer specific information obtained during imaging. Alternatively, in some embodiments, the reconstruction may include reconstruction of a single desired layer or depth below the surface of the subject's skin. Further, as shown for example in FIG. 5B, in some embodiments, the reconstruction may be presented in a two dimensional array format displaying only a region or layer of interest (e.g., the second layer 162 in FIG. 5B).

FIGS. 5C and 5D illustrate experimental laboratory results obtained via presently disclosed data acquisition and processing methods when a chicken breast surface was wiped dry and sprayed with a saline solution, respectively. The determined conductivities of the layers for each of the surface types are shown in the respective layers of FIGS. 5C and 5D. The foregoing experiment utilizes different skin conditions present at the surface of the chicken breast to simulate different skin conditions that may be present at the surface of a subject's skin. As shown, by utilizing an embodiment of the presently disclosed imaging method, it was determined that the conductivity near the surface of the chicken breast (e.g., layers 1 and 2) show the highest level of conductivity change between the dry surface represented in FIG. 5C and the sprayed wet surface represented in FIG. 5D, while the layers farthest from the surface (e.g., layers 3 and 4) show the least variation. Accordingly, the results illustrate that presently disclosed systems and methods may enable acquisition of layer specific hydration information with a reduced sensitivity to skin conditions.

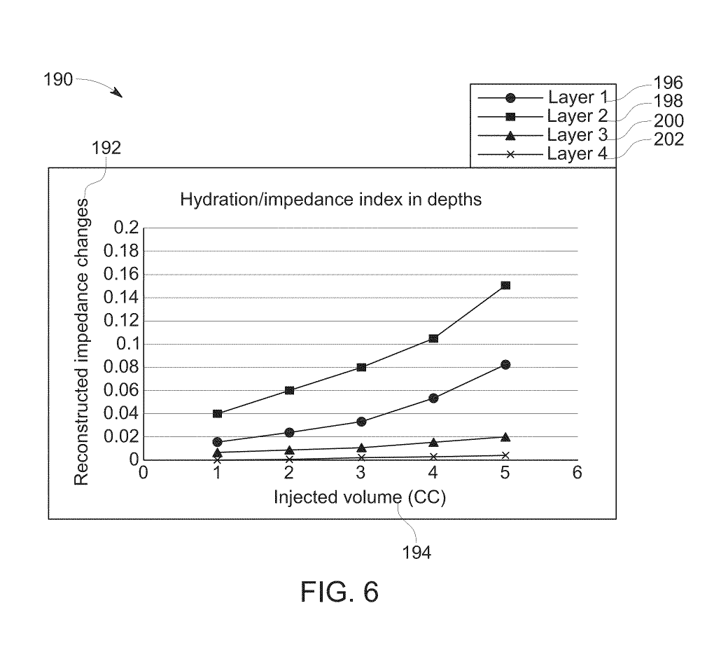

FIG. 6 illustrates a plot 190 having a reconstructed impedance change axis 192 and an injected volume axis 194 and representing experimental results obtained when a chicken breast was injected with different volumes of saline. As shown, when greater volumes of saline were injected into the chicken breast, the reconstructed impedance changes increased for each of layers 196, 198, 200, and 202. This feature demonstrates that presently disclosed systems and methods are capable of being used to detect hydration changes at different levels below the data acquisition surface. It should be noted that the greatest change is shown in layer 2 where the greatest volume of saline was injected. Lesser changes are shown in layer 1 where the saline migrated downward toward the surface. The least change was observed in the deepest layers, 3 and 4, which were furthest from the saline injection.

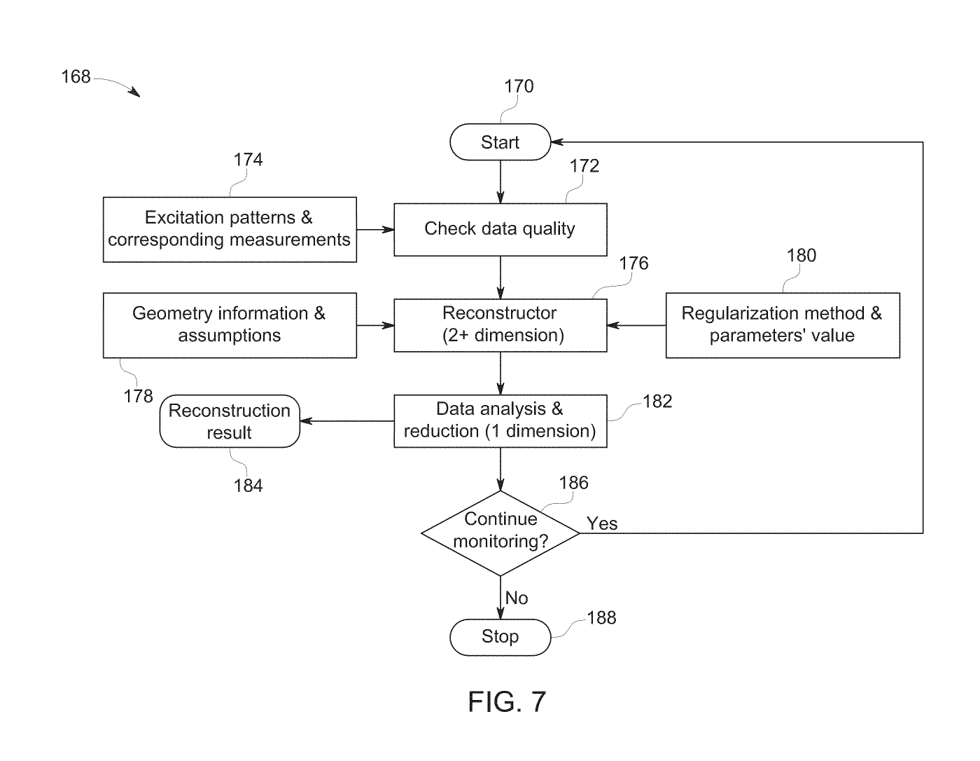

FIG. 7 illustrates an embodiment of a data flow reconstruction method 168. As shown, once the method 168 is initiated (block 170), the quality of the data is checked (block 172), for example, by considering the excitation patterns and measurements obtained by using those patterns (block 174). For instance, in some embodiments, the obtained measurements may be outside a preset accepted range associated with the excitation pattern used to acquire those measurements, and an error may be provided to the operator. This may occur, for example, when the imaging machine is not properly calibrated or a user or operator error has occurred.

If the data quality is approved in block 172, the reconstructor utilizes input regarding geometry information and assumptions 178 (e.g., information regarding the geometry of the imaging system to compute the depth sensitive matrix of the reconstructor) and the regularization method and parameters' value 180 (e.g., selected by a user or preset at setup) to perform a two or three dimensional reconstruction (block 176). In certain implementations, the reconstructor may generate a hydration index or parameter. The output of the reconstructor is then communicated to a data analysis module for the two or three dimensional information to be analyzed and reduced (block 182) to a one dimensional reconstruction result 184, which may be displayed or otherwise communicated to a system operator. In certain embodiments, the method 168 may check if additional monitoring is desired (block 186) and if it is not, the method ends (block 188). Additional monitoring may be desired, for example, in instances in which a subject's condition may be monitored over time or measurements are continually be obtained, and it is desired that the reconstruction be updated as additional measurements are acquired.

In many of the previously disclosed embodiments, electrical impedance tomography results have been discussed. However, it should be noted that as previously mentioned, the disclosed systems and methods are also applicable to other soft-field imaging applications, such as electrical impedance spectroscopy. For example, in some embodiments, excitations may be generated to perform spectroscopy at different depths within a subject, and the reconstructor 42 may extract spectroscopy information at different depths. In this way, certain embodiments may enable examination of how impedance changes at a depth over different frequencies. Further, in certain embodiments, different depths within the same subject may be compared for analysis to include a subject-specific baseline (e.g., compare soft tissue to bone tissue).

In electrical impedance spectroscopy embodiments, the excitation patterns are generated at multiple frequencies such that the system can measure tissue impedances over the frequency range. These impedances can be resolved at different depths due to the spatial encoding of the excitation patterns and at different frequencies due to the temporal encoding of the excitation patterns. The behaviors of the magnitude and the phase of the tissue impedance measurements vary with tissue type and tissue condition (e.g., water content). For example, muscle tissue has a distinctly different impedance spectrum than connective tissue. For further example, the impedance spectrum of connective tissue does not vary greatly with water content since connective tissue does not readily absorb/desorb water, but the impedance spectrum of muscle tissue does vary considerably with water content since muscle tissue can more readily absorb/desorb water.

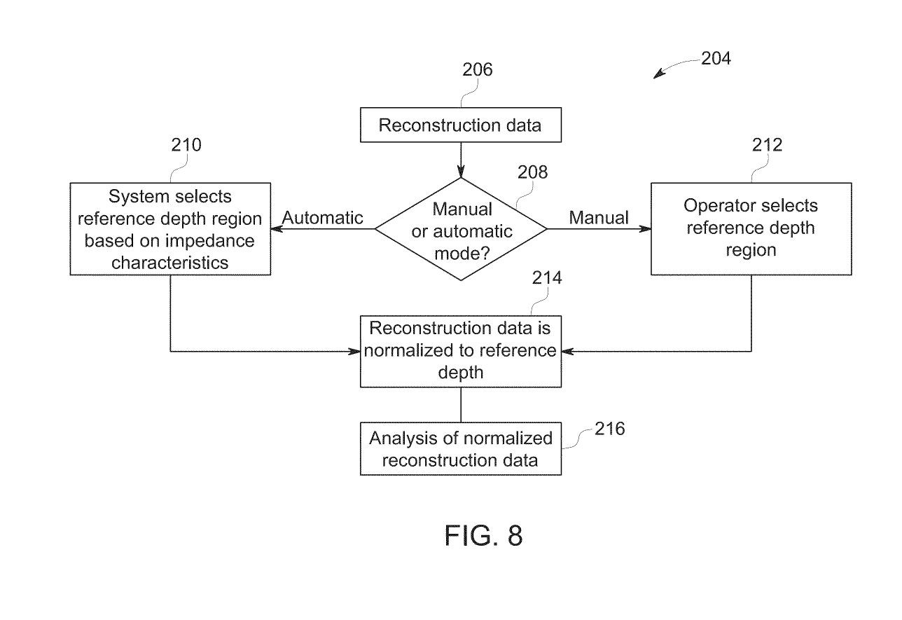

Accordingly, in certain embodiments, reconstruction data may be normalized by using an implementation-specific depth. FIG. 8 illustrates an embodiment of a method 204 for performing such a normalization. In this method 204, reconstruction data 206 is received and an inquiry is made as to whether a manual or automatic mode is desired (block 208). If automatic mode is chosen, a reference depth is determined automatically by recognizing aspects of the impedance or the impedance spectrum of the tissue (block 210). Alternatively, if manual mode is chosen, the reference depth is selected by the user manually, for example, in a numeric (e.g. depth from surface) or graphical (e.g., point and click) manner (block 212).

The method 204 then calls for the reconstruction data to be normalized to a reference depth (block 214), and the normalized reconstruction data may be analyzed (block 216). In such embodiments, the reference depth may be used to normalize the impedance or impedance spectrum of all the depths to provide a subject-specific reconstruction. For example, the user or system may choose a region containing connective tissue and bone as the reference depth due to its relative insensitivity to water content. Other regions, such as muscle tissue, may then be normalized to the reference region to reduce the impact of varying skin, electrode, and instrument measurement errors. Features of this approach may reduce or eliminate the need to perform absolute measurements while still providing clinically useful information.

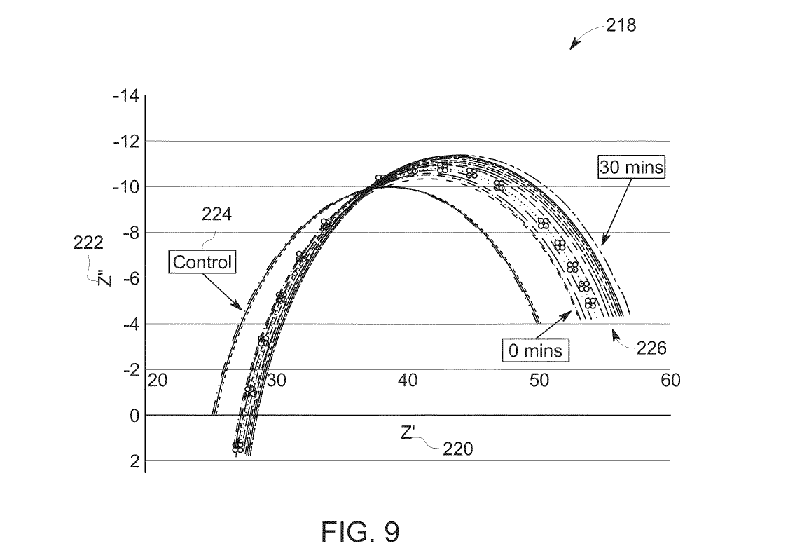

FIG. 9 illustrates an example of a frequency sweep plot 218 obtained by performing electrical impedance spectroscopy on a human subject (with removed outliers for clarity). The illustrated frequency sweep plot 218 (i.e., the Cole-Cole plot) includes the real part of the impedance measurement along the X-axis 220 and the imaginary part along the Y-axis 222. The illustrated Cole-Cole plot 218 includes a control curve 224 corresponding to the subject having the imaged leg in a non-elevated position and a plurality of curves 226 corresponding to the subject having the imaged leg in an elevated position. Each of the plurality of curves 226 corresponds to a frequency sweep performed within the range from 2.5 KHz to approximately 160 KHz. As shown, the plots 226 corresponding to the elevated leg exhibit a consecutive change over time, while the impedance measurement obtained for the control leg does not change consecutively over time, which implies that impedance for the non-elevated leg does not change over time.

It should be noted that the control curve and the plurality of curves 226 corresponding to the elevated leg start at different points along the axes 220 and 222 due to experimental factors (e.g., a variation in position of the legs, an error of the electrode position, etc.). However, the consecutive relative impedance changes are observable over time (0 minutes˜30 minutes) for the plurality of plots 226 corresponding to the elevated leg, which correlate to fluid changes within the elevated leg.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A soft-field tomography system, comprising:
a plurality of electrodes configured to be positioned on a surface of an interrogation region of a subject;
a pattern generator configured to determine one or more excitation patterns for probing a tissue of the subject at one or more predetermined depths from the surface of the subject into the interrogation region, wherein each of the one or more excitation patterns has a spatial sensitivity at one of the one or more predetermined depths;
a plurality of excitation sources coupled to the plurality of electrodes and configured to apply each of the one or more excitation patterns to the plurality of electrodes to excite the plurality of electrodes substantially simultaneously with each of the excitation patterns; and
a plurality of receivers coupled to the plurality of electrodes and configured to measure one or more responses of the subject at the plurality of electrodes to the excitation applied by the plurality of electrodes, wherein each of the one or more responses corresponds to one of the one or more predetermined depths for which the applied excitation pattern has spatial sensitivity.

2. The system of claim 1, comprising a processor configured to reconstruct a conductivity distribution at the one or more predetermined depths within the subject based on the one or more measured responses.

3. The system of claim 1, wherein each of the one or more excitation patterns is generated at one or more frequencies.

4. The system of claim 3, comprising a processor configured to receive data corresponding to the one or more responses and to resolve impedances of the subject over one or more frequencies at the one or more predetermined depths.

5. The system of claim 1, comprising a processor configured to calculate one or more impedance changes at the one or more predetermined depths within the subject based on the one or more measured responses.

6. The system of claim 5, wherein the one or more responses are obtained with one or more working frequencies of the plurality of excitation sources, and the processor is configured to determine one or more hydration level changes based on the one or more impedance changes at the one or more predetermined depths and on the one or more responses.

7. The system of claim 6, wherein the processor is further configured to quantify an edema level at each of the one or more predetermined depths within the subject based on the one or more measured responses.

8. A soft-field tomography system, comprising:
a pattern generator that, in operation, generates one or more excitation patterns suitable for probing a hydration level of a tissue of a subject at one or more predetermined depths from a surface of the subject into an interrogation region of the subject, wherein each of the one or more excitation patterns has a spatial sensitivity at one of the one or more predetermined depths; and
a data analysis module that, in operation, receives one or more measured responses of the subject at a plurality of electrodes to excitation applied by the plurality of electrodes based on the one or more excitation patterns, and determines one or more hydration changes at the one or more predetermined depths within the subject based on the one or more measured responses, wherein each of the one or more measured responses corresponds to the one of the one or more predetermined depths for which the applied excitation pattern has spatial sensitivity.

9. The system of claim 8, wherein the pattern generator is configured to receive feedback from the data analysis module regarding at least one of the one or more measured responses and to modify at least one of the one or more excitation patterns based on the received feedback.

10. The system of claim 8, wherein the pattern generator is configured to receive data corresponding to a feature of the tissue of the subject and to modify at least one of the one or more excitation patterns based on the received feedback.

11. The system of claim 10, wherein the feature of the tissue comprises tissue type, tissue location on the subject, tissue pigment level, tissue thickness, or a combination thereof.

12. The system of claim 8, wherein, in operation, the data analysis module quantifies an edema level at each of the one or more depths within the subject based on a conductivity distribution, an impedance distribution, or a hydration index derived from the one or more measured responses.

13. The system of claim 8, wherein, in operation, the data analysis module generates reconstruction data by reconstructing a conductivity distribution at the one or more depths within the subject based on the one or more measured responses.

14. The system of claim 13, wherein the reconstruction data is normalized to a manually chosen or automatically determined reference depth.

15. An electrical impedance based imaging method, comprising:
applying first excitation signals to a plurality of electrodes positioned on a surface of an interrogation region of a subject;
measuring a first response of the interrogation region of the subject to the excitation applied by the plurality of electrodes based on the first excitation signals;
applying second excitation signals to the plurality of electrodes;
measuring a second response of the interrogation region of the subject to the excitation applied by the plurality of electrodes based on the second excitation signals; and
determining at least one conductivity level at one or more depths below the surface of the subject based on the first response and the second response.

16. The method of claim 15, comprising determining at least one hydration change between the one or more depths below the surface of the subject based on the first and second responses.

17. The method of claim 16, comprising determining an edema level at each of the one or more depths below the surface of the subject based on the first and second responses and the at least one hydration change.

18. The method of claim 15, wherein the first excitation signals comprise a current phase and a current magnitude for each of a plurality of electrodes suitable for forming a first current pattern within the interrogation region of the subject.

19. The method of claim 15, wherein the second excitation signals comprise a current phase and a current magnitude for each of a plurality of electrodes suitable for forming a second current pattern within the interrogation region of the subject.

20. The method of claim 15, wherein the first excitation signals correspond to a first current density pattern generated within the interrogation region and the second excitation signals correspond to a second current density pattern generated within the interrogation region, and wherein the first current density pattern and the second current density pattern are configured to probe different depths below the surface of the subject.

21. The method of claim 15, wherein at least one of the first excitation signals and the second excitation signals is chosen based on a race of the subject, a gender of the subject, a thickness of a tissue of the surface of the subject, a type of body part of the surface of the subject, or a combination thereof.

22. The method of claim 15, comprising applying one or more additional excitation signals to the plurality of electrodes, measuring one or more additional responses of the interrogation region of the subject, and determining the at least one conductivity level based at least in part on the one or more additional responses.
